(19) United States
(12) Patent Application Publication
(10) Pub. No.: US 2012/0101773 A1
(43) Pub. Date: Apr. 26, 2012

(54) METHOD AND DEVICE FOR MEASURING CONDUCTIVITY INFORMATION AND CORRESPONDING MARKERS

(75) Inventors: Alistair Lee Mcewan, Aachen (DE); Matthias Hamsch, Aachen (DE); Roland Eichardt, Aachen (DE); Joachim Kahlert, Aachen (DE)

(73) Assignee: KONINKLIJKE PHILIPS ELECTRONICS N.V., EINDHOVEN (NL)

(21) Appl. No.: 13/382,798

(22) PCT Filed: Jul. 6, 2010
(86) PCT No.: PCT/IB10/53086

§ 371 Date: Jan. 6, 2012

(30) Foreign Application Priority Data
Jul. 8, 2009 (CN) 200910140180.2

(51) Int. Cl. G06F 15/00; G01R 33/44; G01R 27/02

(52) U.S. Cl. 702/150; 324/605; 324/322

(57) ABSTRACT

The invention provides a marker (20). The marker (20) comprises a circuit (22) actuated by a first frequency into conductive status to track position information of an object (40). The circuit (22) of the marker (20) is in a non-conductive status based on the second frequency, and the first frequency is not in the range of the second frequency for measuring the conductivity information of the object (40). The invention further provides a device for measuring conductivity information of the object by generating the first frequency and the second frequency.

### FIELD OF THE INVENTION

The invention relates to a method and device for measuring conductivity information of an object, and markers used for tracking position information of the object.

### BACKGROUND OF THE INVENTION

Device for measuring conductivity information of an object is becoming more and more popular in medical area, for example detecting/monitoring bleeding after an operation, guiding surgical operations, monitoring vital signs etc. The device for measuring conductivity information can be a Magnetic Induction Tomography (MIT) device, a Magnetic Resonance Imaging (MRI) device, vital sign monitoring device etc.

When a device for measuring conductivity information is used for measuring an object, e.g. a human body, an animal body, the movements of the object is inevitable, and the accuracy of the measurement will be affected by the movements. Especially, when a device for measuring conductivity information is used to monitor a patient for a long time, the movement possibility of the patient is much higher, so the accuracy of the measurement could be much lower because of the movements.

For example, MIT is strongly related to the distance between an object and coils of a MIT device, if the distance/relative position between an object and coils of a MIT device is changed, the result of MIT may be affected. Additionally, the movements themselves may lead to changes in the conductivity when considering a fixed volume element of an object.

To reduce movement artefacts, a set of markers is used for tracking position information of an object to adjust the conductivity information measured by the device which is used for measuring the conductivity information of the object.

Currently, the markers can be made from any metallic to be tracked by built-in magnetic field sensors. However, due to the sensitivity of a device for measuring conductivity information, the metallic markers would swamp the conductivity information of an object and affect the accuracy of measuring the conductivity information of the object.

### SUMMARY OF THE INVENTION

An object of this invention is to provide an improved marker used to track position information of an object.

The marker comprises a circuit actuated by a first frequency into a conductive status to track position information of an object, the circuit is in a non-conductive status based on a second frequency which is used for measuring conductivity information of the object, and the first frequency is not in the range of the second frequency.

The advantage is that the marker is designed to track position information of an object independently from measuring conductivity information of the object, so the conductivity information of the object is less swamped by the markers and the measured conductivity information of an object is more accurate.

Another object of this invention is to provide an improved device for measuring conductivity information of an object.

The device for measuring conductivity information of an object comprises:
a generator for generating a first frequency to actuate a set of markers into a conductive status for tracking a first position information of the object, for generating a second frequency to measure conductivity information of the object, and for generating the first frequency to actuate the set of markers into conductive status for tracking a second position information of the object, wherein the set of markers is in a non-conductive status based on the second frequency, and the first frequency is not in a range of the second frequency for measuring the conductivity information of the object,
a receiver for receiving the conductivity information, the first position information and the second position information, and
an adjuster for adjusting the conductivity information based on a difference between the first position information and the second position information.

The advantage is that the generator can generate two different frequencies for tracking position information and conductivity information respectively, and tracking the position information is independent from measuring the conductivity information, so as to avoid the conductivity information is interfered by the set of markers, and the measured conductivity information of an object is more accurate.

The invention also provides a method corresponding to the device for measuring conductivity information of an object.

The invention further provides a computer program used in the method for measuring conductivity information of an object.

Detailed explanations and other aspects of the invention will be given below.

### DESCRIPTION OF THE DRAWINGS

The above and other objects and features of the present invention will become more apparent from the following detailed description considered in connection with the accompanying drawings, in which:

FIG. 1 schematically depicts a system with a device for measuring conductivity information of an object and a set of markers used for tracking positions of the object;

FIG. 2 schematically shows a marker used for tracking position information of an object;

FIG. 3 schematically depicts a method for measuring conductivity information of an object.

The same reference numerals are used to denote similar parts throughout the figures.

### DETAILED DESCRIPTION

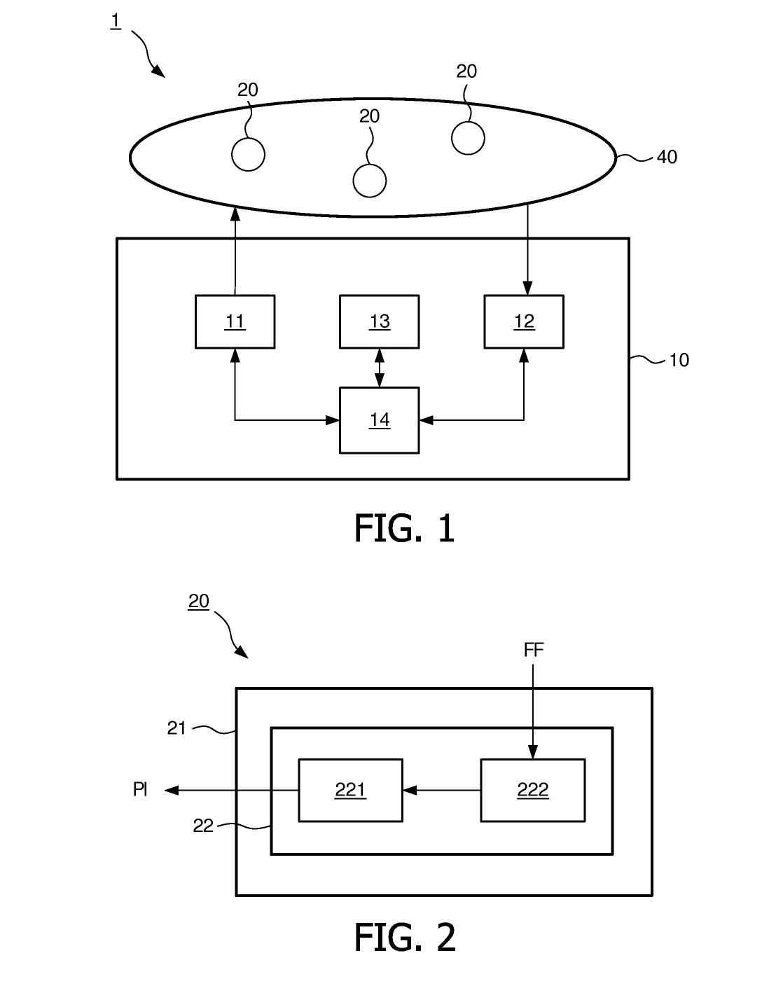

FIG. 1 schematically depicts a system with a device for measuring conductivity information of an object and a set of markers used for tracking position information of the object.

The system 1 comprises a device 10 for measuring conductivity information of an object 40 and a set of markers 20 for tracking movements of the object 40.

The object 40 can be a human body, an animal body etc. The device 10 can be a MIT (Magnetic Induction Tomography) device, a MRI (Magnetic Resonance Imaging) device, or a monitoring device for monitoring vital sign during sleep, exercise, rehabilitation etc. The conductivity information may be impedance information. An image may be reconstructed based on the conductivity information.

The position of the object 40 to be measured may be changed because of movements of itself. The movements may comprise translations, rotations, expansions of a thorax due to inhalation etc., and the movements cause changes of the distance between the markers 20. Thus, the position information of the object 40 can be tracked by obtaining the position information of the set of markers 20, and then the conductivity information measured by the device 10 can be adjusted based on the position information. Furthermore, the position information of the object 40 can be used to identify intervals of movements of the object 40 during a measurement, so as to characterize typical situations of the object 40, e.g. the state of maximum inhalation or exhalation.

The device 10 may comprise a generator 11 or a set of generators 11 for generating a first frequency (e.g. magnetic field) to actuate the set of markers 20 for tracking a first position information of the object 40, for generating a second frequency (e.g. magnetic field) to measure conductivity information of the object 40, and for generating the first frequency again to actuate the set of markers 20 for tracking a second position information of the object 40. The measuring device 10 may also comprise a receiver 12 for receiving the conductivity information, the first position information, and the second position information.

The receiver 12 may comprise a sensor or a set of sensors for collecting the conductive information and position information of the object 40. The position information of the object 40 is reflected by position information of the set of markers 20, and the position information of the set of markers 20 is reflected by conductive information of the set of markers 20 collected by the sensor/sensors of the receiver 12. The position information of the object 40 can be determined by nonlinear dipole localization methods, by a pre-measured look up table of positions, or by other known suitable algorithm.

The device 10 further comprises an adjuster 13 for adjusting the measured conductivity information of the object 40 based on a difference between the first position information and the second position information of the object 40, and a controller 14 for controlling the generator 11, the receiver 12, and the adjuster 13 to work.

For example, three markers 20 are used to track the position information of the object 40 in three dimensions. The impedance of the markers 20 at their working frequencies is fixed, so the coupling between the device 10 and markers 20 is related to the distance from the device 10 to the markers 20, and the distance between the markers 20 and the device 10 reflects the distance between the object 40 and the device 10.

The interval between generating the first frequency and generating the second frequency can be pre-set by a user or a manufacturer of the device 10. The first frequency for the markers 20 can be same or different. The first frequency for all the markers is in a specific frequency range, so that the set of markers 20 can be actuated in a maximal conductive status by the first frequency, the maximal conductive status is called as conductive status in the following. The first frequency is not in the range of the second frequency for measuring the conductivity information of the object 40, and the second frequency is only able to actuate the set of markers 20 into a minimal conductive status which can be neglected for interfering measuring conductivity information of the object 40, so the minimal conductive status is called as non-conductive status in the following. The first frequency is very low and can be neglected for measuring conductivity information of the object 40. The first frequency may be a resonance frequency of the set of markers 20 for actuating the set of markers 20 into the conductive status, so the set of markers 20 can be called as passive markers for working in a passive way. The first frequency may be in a range of 1˜2 MHz and the second frequency may be in a range of 2˜10 MHz.

Based on the first frequency for the set of markers 20, the position information of the object 40 can be tracked independently from measuring the conductivity information of the object 40.

FIG. 2 schematically shows a marker for tracking position information of an object. The marker 20 comprises a covering 21 and a circuit 22 covered by the covering 21. The covering 21 may be made from fabric, and the circuit 22 can be integrated into the covering 21. The circuit 22 comprises a first element 221 and a second element 222 connecting with the first element 221. The first element 221 may comprise a coil or a set of coils. The second element 222 may comprise a quartz resonator designed to be actuated by the first frequency (shown as FF in FIG. 2), so as to cause the first element 221 into the conductive status. Alternatively, the second element 222 may be a ceramic band-pass filter designed to be actuated by the first frequency, so as to cause the first element 221 into the conductive status. The quartz resonators or ceramic band-pass filters can be designed as second element 222 because of their high specific resonant frequencies and widespread availability, so that the quartz resonators and the ceramic band-pass filters can be resonant based on the first frequency for causing the first element 221 into the conductive status.

The marker 20 may also comprise an adhesive element (not shown in FIG. 2) for attaching the marker 20 to the object 40 easily.

If the generator 11 of the device 10 generates the first frequency: the second element 222 of the marker 20 is actuated into resonant, which causes the first element 221 of the marker 20 into conductive status for tracking the position information (shown as PI in FIG. 2) of the object 40, and the first frequency is neglected for measuring the conductivity information object 40.

If the generator 11 of the device 10 generates the second frequency: the second element 222 of the marker 20 is not actuated by the second frequency, which causes the first element 221 of the marker 20 into the non-conductive status, and the conductivity information of the object 40 is measured based on the second frequency without being interfered by the marker 20.

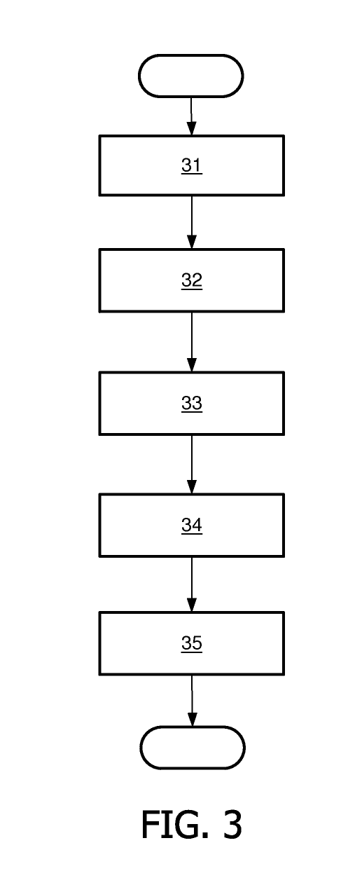

FIG. 3 schematically depicts a method for measuring conductivity information of an object.

The method comprises the following steps:

A first step 31 is to generate a first frequency for actuating the set of markers 20 into a conductive status to track a first position information of the object 40. The first frequency is neglected to measure the conductivity information of the object 40.

A second step 32 is to generate a second frequency for measuring the conductivity information of the object 40. The set of markers 20 is in a non-conductive status based on the second frequency for avoiding interfering measuring the conductivity information of the object 40.

A third step 33 is to generate the first frequency for actuating the set of markers 20 into the conductive status to track a second position information of the object 40.

A fourth step 34 is to receive the conductivity information, the first position information, and the second position information.

A fifth step 35 is to adjust the conductivity information according to a difference between the first position information and the second position information.

A computer program is integrated in the controller 14 for implementing the steps of the method for measuring conductivity information of the object.

It should be noted that the above-mentioned embodiments illustrate rather than limit the invention and that those skilled in the art will be able to design alternative embodiments without departing from the scope of the appended claims. In the claims, any reference signs placed between parentheses shall not be construed as limiting the claim. The word “comprising” does not exclude the presence of elements or steps not listed in a claim or in the description. The word “a” or “an” preceding an element does not exclude the presence of a plurality of such elements. The invention can be implemented by unit of hardware comprising several distinct elements and by unit of a programmed computer. In the system claims enumerating several units, several of these units can be embodied by one and the same item of hardware or software. The usage of the words first, second and third, et cetera, does not indicate any ordering. These words are to be interpreted as names.

1. A marker (20) comprising a circuit (22) actuated into a conductive status by a first frequency for tracking position information of an object (40), wherein the circuit (22) is in a non-conductive status based on a second frequency used for measuring conductivity information of the object (40), and the first frequency is not in the range of the second frequency for measuring the conductivity information of the object (40).

2. A marker as claimed in claim 1, wherein the circuit (22) comprises a first element (221) connecting with a second element (222), and the second element (222) is actuated by the first frequency to cause the first element (221) into the conductive status.

3. A marker as claimed in claim 2, wherein the second element (222) comprises a quartz resonator or a ceramic band-pass filter to be actuated by the first frequency for causing the first element (221) into the conductive status.

4. A marker as claimed in claim 2, wherein the first element (221) comprises a coil or a set of coils.

5. A marker as claimed in claim 1, wherein the first frequency is in a range of 1˜2 MHz, and the second frequency is in a range of 2˜10 MHz.

6. A device (10) for measuring conductivity information of an object, and the device (10) comprising:
a generator (11) for generating a first frequency to actuate a set of markers (20) into a conductive status for tracking a first position information of the object (40), for generating a second frequency to measure conductivity information of the object (40), and for generating the first frequency to actuate the set of markers (20) into the conductive status for tracking a second position information of the object (40), wherein the set of markers (20) is in a non-conductive status based on the second frequency, and the first frequency is not in the range of the second frequency for measuring the conductivity information of the object (40),
a receiver (12) for receiving the conductivity information, the first position information and the second position information, and
an adjuster (13) for adjusting the conductivity information based on a difference between the first position information and the second position information.

7. A device as claimed in claim 6, wherein an interval between generating the first frequency and generating the second frequency is pre-set.

8. A device as claimed in claim 6, wherein the first frequency is in a range of 1˜2 MHz and the second frequency is in a range of 2˜10 MHz.

9. A device as claimed in claim 6, wherein the device (10) is a Magnetic Induction Tomography device, a Magnetic Resonance Imaging device, or a vital sign monitoring device.

10. A system comprising a device as claimed in claim 6.

11. A method of measuring conductivity information of an object (40), comprising the steps of:
generating (31) a first frequency for actuating the set of markers (20) into conductive status to track a first position information of the object (40),
generating (32) a second frequency to measure conductivity information of the object (40), wherein the set of markers (20) is in a non-conductive status based on the second frequency, and the first frequency is not in the range of the second frequency for measuring the conductivity information of the object (40),
generating (33) the first frequency for actuating the set of markers 20 into conductive status to track a second position information of the object (40),
receiving (34) the conductivity information, the first position information, and the second position information, and
adjusting (35) the conductivity information according to a difference between the first position and the second position.

12. A computer program used in a method for measuring conductivity information of an object, the method comprising the steps of:
generating (31) a first frequency to actuate the set of markers (20) into a conductive status for tracking a first position information of the object (40),
generating (32) a second frequency to measure conductivity information of the object (40), wherein the set of markers (20) is in a non-conductive status based on the second frequency, and the first frequency is not in the range of the second frequency for measuring the conductivity information of the object (40),
generating (33) the first frequency to actuate the set of markers 20 into conductive status for tracking a second position information of the object (40),
receiving (34) the conductivity information, the first position information, and the second position information, and
adjusting (35) the conductivity information according to a difference between the first position information and the second position information.
